(19) United States
(12) Patent Application Publication
(10) Pub. No.: US 2011/0202819 A1
(43) Pub. Date: Aug. 18, 2011

(54) Configurable Error Correction Encoding and Decoding

(76) Inventors: Yuan Lin, Hudson, MA (US); Philip R. Moorby, South Hampton, NH (US)

(21) Appl. No.: 12/705,460

(22) Filed: Feb. 12, 2010

(51) Int. Cl. H03M 13/27; G06F 11/10

(52) U.S. Cl. 714/776; 714/E11.032

(57) ABSTRACT

A system and method are disclosed performing error correction on data by a processor. Received data is demultiplexed into a first demultiplexer output and a second demultiplexer output. Stored instructions are executed by a processor to decode the first demultiplexer output and a deinterleaver output to produce a decoded output. Stored instructions are executed by a processor to interleave the decoded output to produce an interleaved output. Stored instructions are executed by a processor to decode the interleaved output and the second demultiplexer output to produce decoded data. Stored instructions are executed by a processor to deinterleave the decoded data. The deinterleaved data is output.

### BACKGROUND

Digital data may be communicated, for example via broadcast, from a source to a destination. Digital data for transmission may be encoded at a source before its transmission to the destination. The digital data received by the destination may then be decoded. Transmission of the digital data may introduce errors into the digital data, for example during wireless transmission of the data. High performance error correction codes, such as turbo codes, were developed to correct errors introduced into digital transmissions. For example, turbo codes are used to communicate data over bandwidth or latency constrained communication links which experience noise that corrupts the communicated data

Turbo decoding is implemented in hardware and requires large amounts of processing cycles. Additionally, the hardware to implement turbo codes is expensive and typically not configurable.

### SUMMARY

Embodiments of the present invention allow for performing error correction on data by a processor. In a first claimed embodiment, a method is disclosed for performing error correction on data by a processor. Received data is demultiplexed into a first demultiplexer output and a second demultiplexer output. Stored instructions are executed by a processor to decode the first demultiplexer output and a deinterleaver output to produce a decoded output. The decoded output is interleaved by stored instructions executed by a processor to interleave to produce an interleaved output. Stored instructions are executed by a processor to decode. The interleaved output is decoded by instructions executed by a processor and the second demultiplexer output to produce decoded data. Stored instructions are then executed by a processor to deinterleave the decoded data. The deinterleaved data is output. In some embodiments, the interleaved output can also be the decoder output if deinterleaving is applied onto the interleaved output

In a second claimed embodiment, a system is disclosed for performing error correction. The system includes a processor and software modules stored in memory. A demultiplexing module stored in memory may be executed by a processor to demultiplex an input into a first demultiplexer output and a second demultiplexer output. A first decoder module may be executed by a processor to decode the first demultiplexer output and a deinterleaver output to produce a decoded output. An interleaver module may then be executed to deinterleave the decoded output to produce an interleaved output. A processor may execute a second decoder module to decode the interleaved output and the second demultiplexer output to produce decoded data. A deinterleaver module stored in memory may be executed by a processor to deinterleave the decoded data and provide deinterleaved data.

In a third claimed embodiment, a computer-readable storage medium is disclosed that has stored thereon instructions executable by a processor to perform a method for performing error correction on data by a processor. Received data is demultiplexed into a first demultiplexer output and a second demultiplexer output. Stored instructions are executed by a processor to decode the first demultiplexer output and a deinterleaver output to produce a decoded output. Stored instructions are executed by a processor to interleave the decoded output to produce an interleaved output. Stored instructions are executed by a processor to decode the interleaved output and the second demultiplexer output to produce decoded data. Stored instructions are executed by a processor to deinterleave the decoded data. The deinterleaved data is output.

### BRIEF DESCRIPTION OF FIGURES

FIG. 1 is a diagram of an exemplary wireless network environment.

FIG. 2 is a block diagram of an exemplary error correction decoder.

FIG. 3 is a flowchart of an exemplary method for performing error correction.

FIG. 4 is a diagram of an exemplary trellis structure.

FIG. 5 is a block diagram illustrating an exemplary error correction decoder that pre-computes calculations before performing decoding iterations.

FIG. 6 is a block diagram illustrating an exemplary error correction decoder with decoding calculations incorporated into input calculations.

FIG. 7 is a diagram of an exemplary trellis-vector array.

FIG. 8 is a block diagram illustrating an exemplary error correction decoder that combines SISO decoder computations with output operations.

FIG. 9 is a block diagram of exemplary system for running error correction decoder software.

### DETAILED DESCRIPTION

The present technology implements high performance error correction codes, such as for example turbo codes, as one or more software modules. The present technology may implement an error correction encoder on a transmitter and an error correction decoder on a receiver. One or more software modules are used to implement decoders, interleavers, and deinterleavers, combinations of these, or additional software modules that make up each error correction encoder and decoder. The software modules may iteratively process an input in a feedback loop to provide an error corrected output data. The software modules may be configured to utilize one or more variations that improve the efficiency of the decoder or encoder.

Implementation of high performance error correction codes as software modules allows for a faster, cheaper and more dynamic implementation of error correction that previously available. Hardware implemented error correction codes required expensive integrated circuits, such as non-programmable ASICs, to implement the codes. The error correction hardware was not adjustable or configurable. Unlike a hardware implementation, software implementation of high performance error correction codes as disclosed herein provides a cheaper and configurable solution to correcting errors in data transmissions such as wireless transmissions.

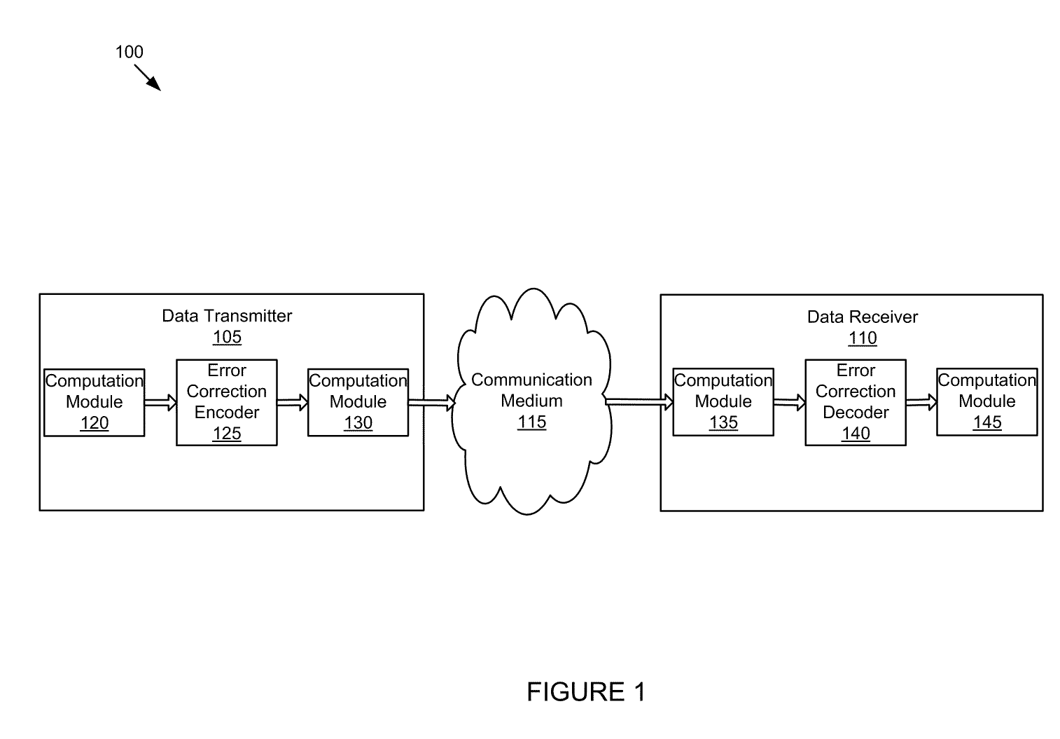

FIG. 1 is a diagram of an exemplary wireless network environment 100. Data transmitter 105 and data receiver 110 are communicatively coupled via communication medium 115. Communication medium 115 may include any medium over which data communication may be corrupted by introduction of noise to the data. Examples of suitable communication mediums include wireless networks such as cellular networks and Wi-Fi networks. The data transmitter 105 may include computation module 120, error correction encoder 125, and computation module 130. The computation module 120 is communicatively coupled with the error correction encoder 125, which is communicatively coupled with the computation module 130. Computation modules 120 and 130 may process data, for example by digital signal processing, to provide error correction encoder 125 with input data (computation module 120) and process data output by correction encoder 125 (computation module 130).

Data receiver 110 may include computation module 135, error correction decoder 140, and a computation module 145. The computation module 135 provides input data to error correction encoder 140, which provides output data to computation module 145. Computation modules 135 and 145 may process data, for example by digital signal processing, for processing by data receiver 110.

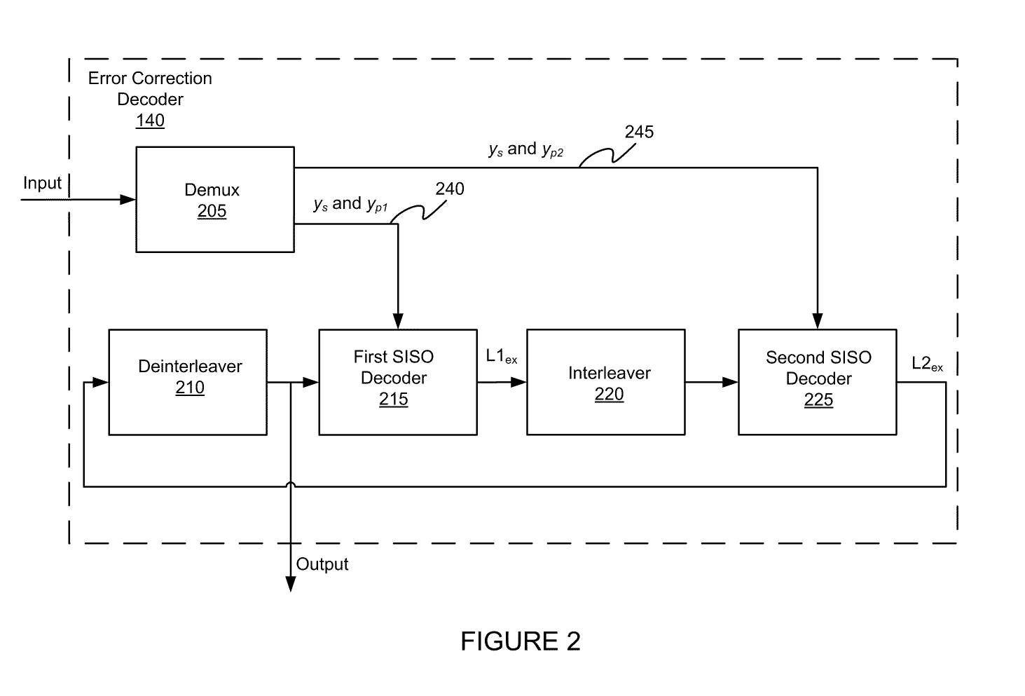

FIG. 2 is a block diagram of an exemplary error correction decoder 140 according to the present technology. The error correction decoder 140 may include software modules stored in memory and executed by a processor to decode data which is encoded by error correction encoder 125 and transmitted by data transmitter 105. Error correction decoder 140 may include a demultiplexer (or demux) 205, deinterleaver 210, first soft-in soft-out (SISO) decoder 215, interleave 220, and second SISO decoder 225.

Error correction decoder 140 receives an input data array y by demux 205, for example from computation module 135. Input data array y may include a systematic array yₛ and parity input data arrays yₚ₁ and yₚ₂. Each of data arrays yₛ, yₚ₁, and yₚ₂ may include Sᵢₙ number of data elements and be concatenated together to form input data array y. In an alternate embodiment, the input data array y may be an intermixing of the data elements of data arrays yₛ, yₚ₁, and yₚ₂. In one exemplary embodiment, yₛ is concatenated with an intermixing of yₚ₁, and yₚ₂. Demux 205 may separate the concatenated data arrays to provide a data array including yₛ and yₚ₁ to first SISO decoder 215 and a data array including yₛ and yₚ₂ to second SISO decoder 225.

Interleaver 220 receives an output data array of first SISO decoder 215 and rearranges the data elements within the array. The rearrangement of the data elements by interleaver 220 is defined by a protocol associated with the data communication, such as for example wideband code division multiple access (W-CDMA), code division multiple access (CDMA), 4G, or Long Term Evolution (LTE). After rearranging data elements within the received data array, interleaver 220 outputs the rearranged data array to second SISO decoder 225.

Deinterleaver 210 rearranges data elements in an order opposite to the rearrangement of interleaver 220. As a result, the data elements rearranged from a first arrangement to a second arrangement by interleaver 220 are arranged back to the first arrangement by deinterleaver 210. Deinterleaver receives a data array output from second SISO decoder 225 and provides a rearranged output to first SISO decoder 215.

The first SISO decoder 215 and the second SISO decoder 225 each process data elements of multiple arrays received by the decoder and output a data array to be rearranged by interleaver 220 or deinterleaver 215. First SISO decoder 215 and second SISO decoder 225 may each implement a MAX*-Log-MAP algorithm (referred to as a MAX* decoder herein). A MAX* decoder processes input data arrays by determining a branch-metric calculation (BMC), an alpha trellis states calculation (alpha), a beta trellis states calculation (beta), and a log-likelihood ratio calculation (LLC). Each calculation is performed for each data element over the entire input array. In one embodiment, the computations performed in the first SISO decoder 215 and the second SISO decoder 225 are the same, though performed on different value data elements.

To calculate the LLC, values for the alpha trellis state, gamma trellis state, and beta trellis state at different times k are combined. If sₖ represents the alpha, gamma, and beta trellis state values at time k, then the likelihood values Lₖ at time k may be given by:

Lₖ=alphaₖ₋₁(sₖ₋₁)+gammaₖ(sₖ₋₁, sₖ)+betaₖ(sₖ). eq. 1

Each trellis state sₖ may be a vector that comprises v fixed-point data elements, where v is defined by a protocol standard that controls the data transmission, such as LTE, W-CDMA, a Wi-Fi standard, a cellular communication standard, or other standard. Alphaₖ₋₁ (sₖ₋₁) is the alpha metric (alpha) that facilitates calculation of the probability of the current state based on the input values before time k. Gammaₖ (sₖ₋₁, sₖ) is the BMC that facilitates calculation of the probability of the current state transition. Betaₖ(sₖ) facilitates calculation of the probability of the current state given the future input values after time k. Alpha and beta calculations may be determined recursively as:

alphaₖ(sₖ)=max*(alphaₖ₋₁(sₖ₋₁)+gammaₖ(sₖ₋₁, sₖ)), and eq. 2

betaₖ(sₖ)=max*(betaₖ₊₁(sₖ₊₁)+gammaₖ₊₁(sₖ, sₖ₊₁)) eq. 3

The alpha computation may be a forward trellis computation and the beta computation may be a backward trellis computation. Let s¹ and s⁰ be the 1-branch and 0-branch trellis state transitions, respectively. The soft output value LLC at time k is defined by subtracting the maximum likelihood values of the 1-branch state transitions from the maximum likelihood values of the 0-branch state transitions, as indicated by:

LLCₖ=max*ₛ₁(Lₖ)−max*ₛ₀(Lₖ). eq. 4

The output of LLCₖ is provided as an output of a SISO decoders (i.e. L1ex and L2ex in FIG. 2). The max-star (max*) operation may be defined by max*(a, b)=max(a, b)+fₐₚₚᵣₒₓ(|a−b|), where fₐₚₚᵣₒₓ(x) is an approximation function for f_{c}(x), and f_{c}(x)=ln(1+e^{-x}). The BMC calculation, gammak₍ₛₖ₋₁,sₖ), is defined by the following equation,

gammaₖ[i]=yₛ[k]*met[i][0]+y_{p1/p2}[k]*met[i][1]+extr[k], i:1˜m, k:1˜Sₒᵤₜ eq. 5

where met[a][b] may be a metric vector as defined by the protocol standard, y_{p1/p2} is yₚ₁ for the first SISO decoder 215, and y_{p1/p2} is yₚ₂ for the second SISO decoder 225. The extr term may be an extrinsic data array output by each SISO decoder to interleaver 220 (L1ex) or deinterleaver 210 (L2ex).

A feedback loop may be created as a number of processing iterations are performed on a data array input. The demuxed input signal is provided to first SISO decoder 215 and second SISO decoder 225, and the first SISO decoder 215 perform calculations on the received data array. The first SISO decoder 215 provides extrinsic output L1ex to interleaver 220. Interleaver 220 rearranges the data elements within the received data array and provides the rearranged data array to second SISO decoder 225. Second SISO decoder 225 receives the interleaved data array as well as a demuxed input data array, decodes the received data arrays, and provides an extrinsic output L2ex to deinterleaver 210. Deinterleaver rearranges the data elements to their previous position within the array and the data array is provided to first SISO decoder 215, where process may be repeated. The iterative process may be repeated several times until an acceptable level of error correction has been achieved or is likely to have been achieved, such as for example eight iterations. In some embodiments, error correction is performed until a likelihood of correction is reached.

The correction likelihood may be dependent of many factors, some of which may be determined externally from the error correction decoder. For example, wireless protocols may have provisions for data throughput that depends on if a wireless device is detected to by moving or stationary. In some protocols, more data may be throughput to the device when it is stationary than moving. When there is more data throughput (i.e., when the device is relatively stationary), the channel conditions may dictate that a higher level of correction likelihood may be required for transmitted data. A lower level of correction likelihood may be required when a wireless device is determined to be moving and receiving less data throughput.

An output data array may be provided by deinterleaver 210 to computation module 145 for further processing. Generally speaking, the output data array may have a size of Sₒᵤₜ=Sᵢₙ/3. In different embodiments, the output data array may have a different size, such as for example Sₒᵤₜ=Sᵢₙ/3-4 for an LTE protocol. Each data element in the output array may be a one-bit binary number. The output data array may also be provided as the output of interleaver 220.

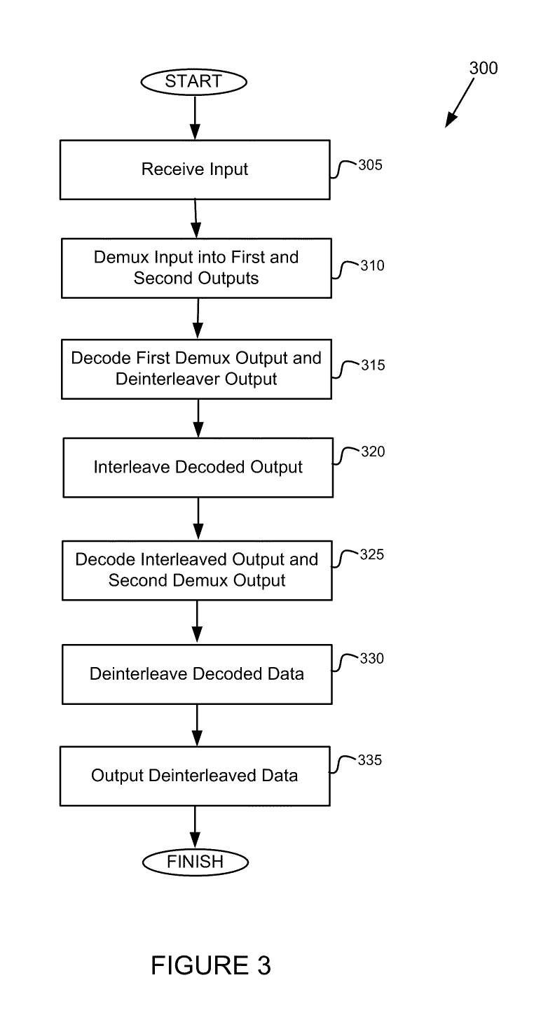

FIG. 3 illustrates a flowchart 300 of an exemplary method for performing error correction. In step 305, demux 205 of the error correction decoder 140 receives input. The input may be received from computation module 135 and may include data arrays yₛ, yₚ₁, and yₚ₂.

The input is demultiplexed (demuxed) into a first demux output 240 and a second demux output 245 at step 310. The first demux output 240 may include yₛ and yₚ₁ and the second demux output 240 may include yₛ and yₚ₂.

First SISO decoder 215 decodes the first demux output 240 and an output of deinterleaver 210 at step 315. The output L1ₑₓ of the first SISO decoder 215 and the first demux output may be processed as discussed above with respect to FIG. 2.

Interleaver 220 interleaves the decoded output L1ₑₓ. The resulting interleaved output has rearranged data elements within a data array and is output to second SISO decoder 225 at step 320.

Second SISO decoder 225 decodes the output of the interleaver 200 and the second demux output 245 in step 325. The second SISO decoder 225 outputs L2ₑₓ to the input of the deinterleaver 210. Deinterleaver 210 deinterleaves the decoded data at step 330 by rearranging the data elements within the received data array into the previous positions.

The output of the deinterleaver 210 is provided to first SISO decoder 215 in step 335. Error correction decoder 140 provides an output signal at step 335. The output signal can be the output of deinterleaver 210 or interleaver 220. The method of FIG. 3 can be iterated a number of times before the output of the error correction decoder 140 is used. For example, the number of iterations may be eight, seven, or some other number.

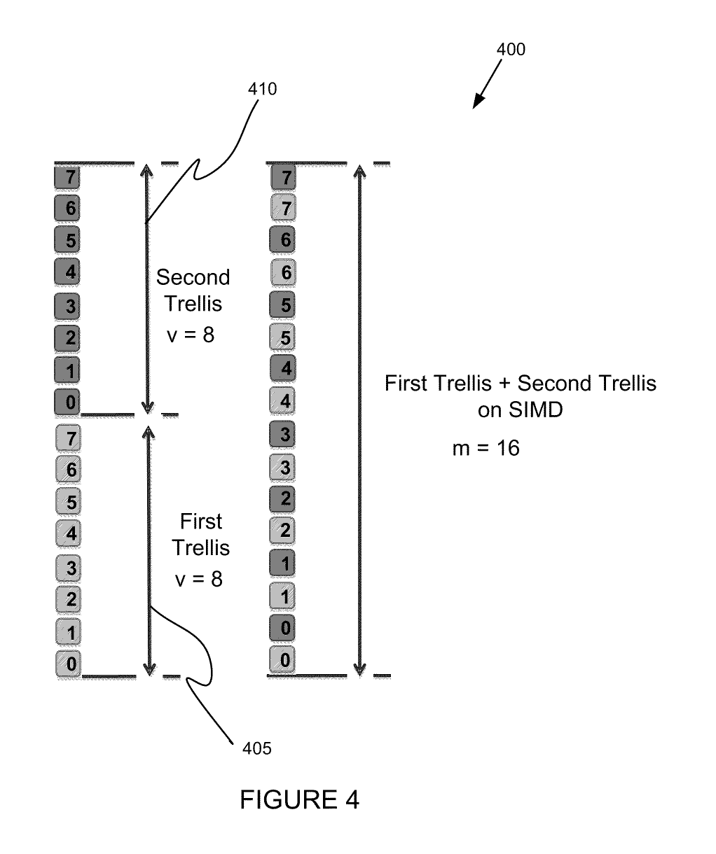

In addition to the advantages of implementing the above described error correction technology on software, a number of variations may be implemented to further enhance the efficiency and speed of the error correction calculations. Representative embodiments of variations to the error correction technology are discussed below with respect to FIG. 4-8.

FIG. 4 illustrates two parallel trellis state-vectors 400 for processing BMC, alpha, beta and LLC calculations in parallel. The error correction decoder 140 can be implemented on a processor with single instruction multiple data (SIMD) processing capabilities. A typical SIMD lane may be utilized as a computational unit having a multiplication, addition, and optionally other computation capability.

In one embodiment, a method is contemplated of using a programmable processor with SIMD processing capabilities to calculate the four steps (discussed herein) of the MAX* decoder, where the number of SIMD lanes, m, is greater or equal to the trellis vector width, v, of the first trellis 405 and the second trellis 410.

Let m[k], k:1˜m be the SIMD lanes, where m≧v. Multiple BMC/alpha/beta/LLC calculations can be performed in parallel on the SIMD lanes, where the number of BMC/Alpha/Beta/LLC calculations, n, is defined as n=m/v. In one embodiment, the mapping of the multiple BMC/alpha/beta/LLC calculations onto SIMD lanes may be defined by the following four equations.

m[i*n+l]=gammaₖ[l][i], i:1˜v, l:1˜n

m[i*n+l]=alphaₖ[l][i], i:1˜v, l:1˜n

m[i*n+l]=betaₖ[l][i], i:1˜v, l:1˜n

m[i*n+l]=LLCₖ[l][i], i:1˜v, l:1˜n

Hence, the n BMC calculations that are performed in parallel on the SIMD lanes are gammaₖ[l], l:1˜n. The n calculations for alpha, beta and LLC performed in parallel on the SIMD lanes are alphaₖ[l], betaₖ[l], and LLCₖ[l], respectively, for l:1˜n. In the embodiment depicted in FIG. 4, m is equal to v plus v (8+8) which, in this case, equals 16. However, it is contemplated that v and m may be equal to other values.

The parallel processing configuration of the present technology advantageously differs from normal SIMD usage which processes a single data array at a time. Processing a single data array at a time provides for wasted resources when the data array has fewer elements than the number of SIMD lanes, as the leftover SIMD lanes are not used. The present technology thus increases processing efficiency by utilizing all SIMD lanes.

In some embodiments, portions of the LLC can be determined prior to performing multiple iterations by the error correction decoder of FIG. 2. For example, a portion of the branch metric calculation (BMC) can be pre-computed, stored and accessed when needed. Pre-computing portions of the LLC enables a SISO decoder to perform calculations faster by reducing the required processing cycles to determine the LLC.

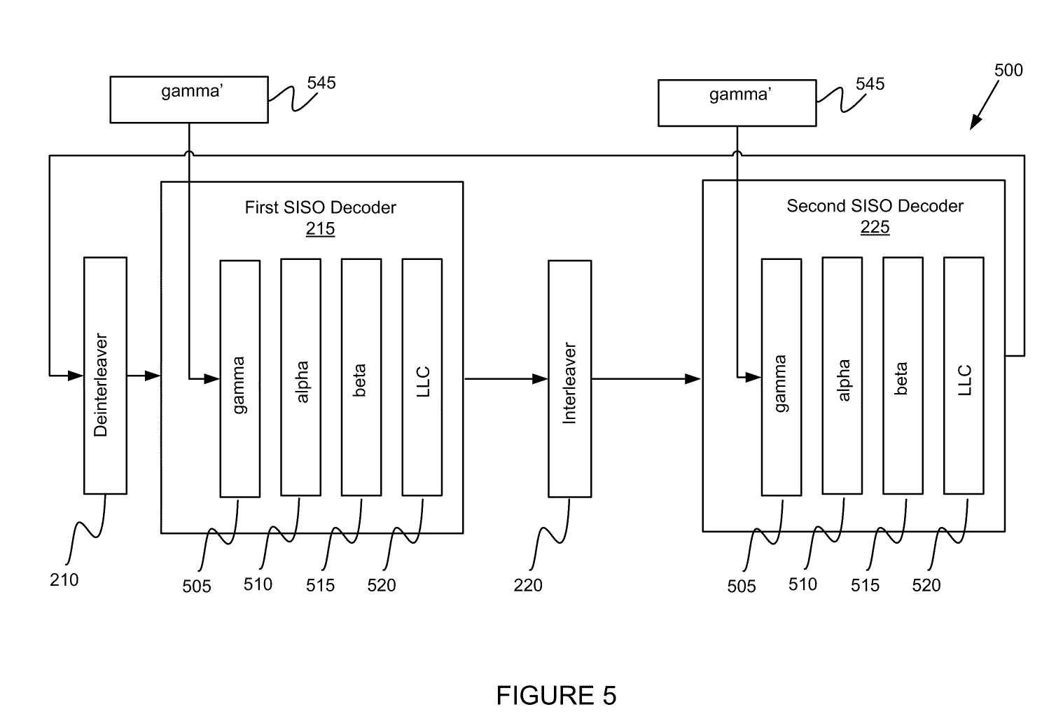

FIG. 5 is a block diagram illustrating an exemplary error correction decoder that pre-computes calculations before performing decoding iterations. Similar to the system of FIG. 2, the decoder includes a feedback loop involving first SISO decoder 215 providing an output to interleaver 220. Interleaver 220 provides an interleaved signal to second SISO decoder 225. The second SISO decoder 225 then provides a signal to deinterleaver 220.

The first SISO decoder 215 may determine values for gamma, alpha, beta and LLC, as represented by reprehensive blocks gamma 505, alpha 510, beta 515, and LLC 520. The second SISO decoder 225 software module may also determine values for gamma, alpha, beta and LLC. Gamma (BMC) may be determined as the sum of three data arrays which include branch metric values based on systemic bits (BMs), branch metric values based on parity bits (BMp), and an extrinsic information portion. A gamma data array may be represented as three data arrays as follows:

gammaₖ[i]=yₛ[k]*met[i][0]+y_{p1/p2}[k]*met[i][1]+extr[k], i:1˜v, k:1˜Sₒᵤₜ eq. 7

In an error correction decoder 140 where multiple iterations are performed before the output array is produced, the values in BMs and BMp are pre-computed and may be stored as SIMD data arrays in memory. Hence, the pre-computed portion of gamma may include branch metric values based on systemic bits (BMs) and branch metric values based on parity bits (BMp).

A portion of the gamma calculation corresponding to branch metric values based on systemic bits (BMs) and branch metric values based on parity bits (BMp), the first and second data arrays in equation 7, comprise gamma′ which can be pre-computed before iterations are performed.

The pre-computer portion gamma′ is illustrated in equation 8. During the error correction decoder 140 computation, BMC values (gammaₖ) are computed by loading the gamma′ₖ array from memory, and adding the BMC values to the extrinsic information, as shown in Equation 9.

gamma′ₖ[i]=yₛ[k]*met[i][0]+y_{p1/p2}[k]*met[i][1], i:1˜v, k:1˜Sₒᵤₜ eq. 8

gammaₖ[i]=gamma′ₖ[i]+extr[k], i:1˜v, j:1˜Sₒᵤₜ eq. 9

In some embodiments, calculations or other processing performed by a SISO decoder may be performed outside error correction decoder 140. Shifting the calculations that may occur in a SISO decoder to outside the error correction decoder 140 enables faster processing and more efficient operation of error correction decoder 140.

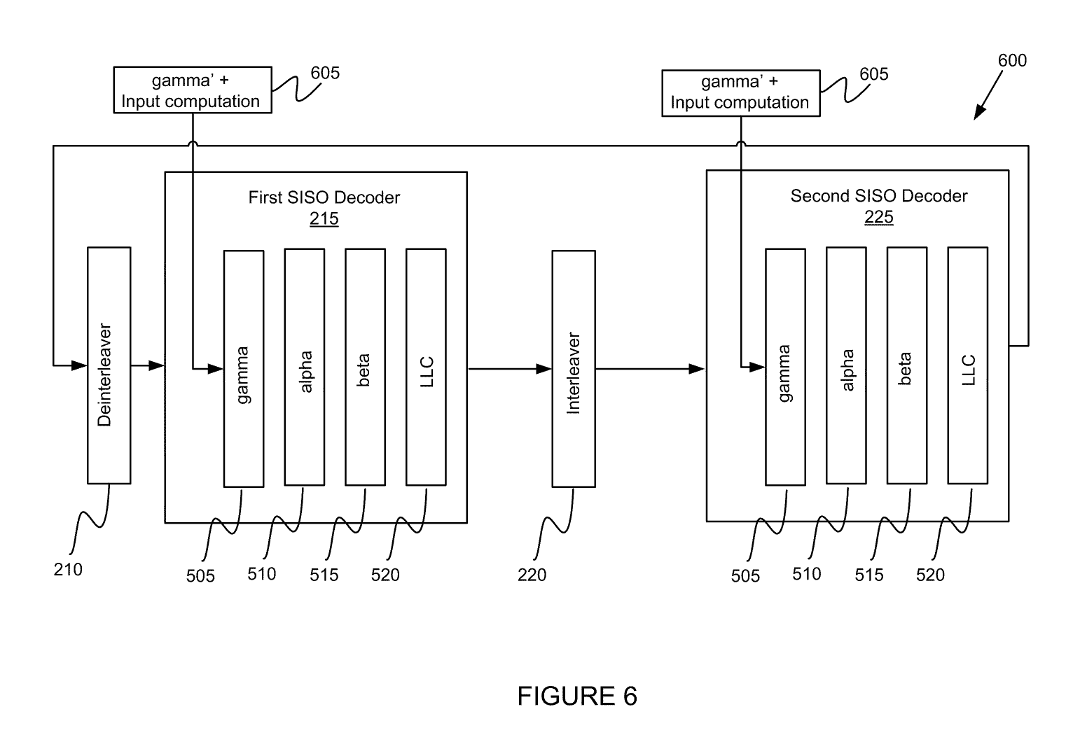

FIG. 6 is a block diagram illustrating an exemplary error correction decoder with decoding calculations incorporated into input calculations. The block diagram of FIG. 6 is similar to the block diagram of FIG. 5, including a deinterleaver 210, first SISO decoder 215, interleaver 220, and second SISO decoder 225 in a feedback loop. An input computation provided to the decoder system includes typical input calculations performed on a data array as well as a portion of the calculations typically performed within a SISO decoder, such as for example a portion of the calculations to determine gamma.

The error correction decoder of FIG. 6 is illustrated with gamma (discussed above with respect to FIG. 5) and an input calculation determined externally to SISO decoder 1 via block 605. By determining gamma′ and an input determination by software other than first SISO decoder, computation operations and memory operations can be reduced and the error correction decoder can execute more efficiently. More specifically, gamma and input calculation computations may be performed before multiple iterations of turbo decoding, which in turn decreases overall computation time of the error correction decoder.

The input computation operations may include input data arrays (yₛ, yₚ₁, and yₚ₂) of the error correction decoder. Let y[k] be a data element in the error correction decoder's input arrays (y[k]εyₛ, yₚ₁, yₚ₂, 1≦k<Sin). The input computation operations for y[k] are defined as any sequence of software operations that comply with three steps. A first step includes arithmetic and memory load/store operations for computing y[k], where y[k]=fₐ(k), 1≦k<Sᵢₙ). A second step includes the calculation of a memory location, y_{index}[k], in the input array for y[k] (y_{index}[k]=f_{b}(k), 1≦k<Sᵢₙ). The memory address of the input being stored is y_{index}[k]. The third step includes storing y[k] into the error correction decoder 140 input array at memory location y_{index}[k] (y_{s/p1/p2}[y_{index}[k]]=y[k], 1≦k<Sᵢₙ). Hence, the three steps involve computing a function, calculating a memory location, and storing the function value at the memory location.

An example of this type of input computation operations is the LTE rate matcher. In an LTE rate matcher, the first step is memory load operation of y[k]. The second step is the calculation of Y_{rateMatcherIndex}[k], as defined by the LTE protocol standard. The third step may be y_{s/p1/p2}[y_{RateMacherIndex}[k]]=y[k], 1≦k<Sᵢₙ.

The gamma′ₖ SIMD operations (equation 8) are combined with fₐ(k) computation as shown by the following seven equations.

gamma′k=gamma1′k+gamma2′k, i:1˜v, k:1˜Sout

gamma1′k=ys[k]*met[i][0], i:1˜v, k:1˜Sout

gamma2′k=yp1/p2[j]*met[i][1], i:1˜v, j:1˜Sout

y′[k]=gamma1′k+fa(k), k:1˜Sout

y′[k]=gamma2′((k−Sout)/2)+fa(k), k:Sout+1˜Sin

y′index[k]=f′b(k), k:1˜Sin

y′ₛ/yₚ₁/yₚ₂[y′index[k]]=y′[k], 1<k<Sin

As indicated above, y′[k] represents the combined operation of y[k] and gamma′ₖ. The SIMD index of y′[k] in the modified error correction decoder 140 input arrays (y′ₛ, y′ₚ₁, y′ₚ₂) is y′_{index}[k]. In this exemplary method, (y′ₛ, y′ₚ₁, y′ₚ₂) are SIMD data arrays that are used as error correction decoder 140 input arrays in-place of (yₛ, yₚ₁, yₚ₂).

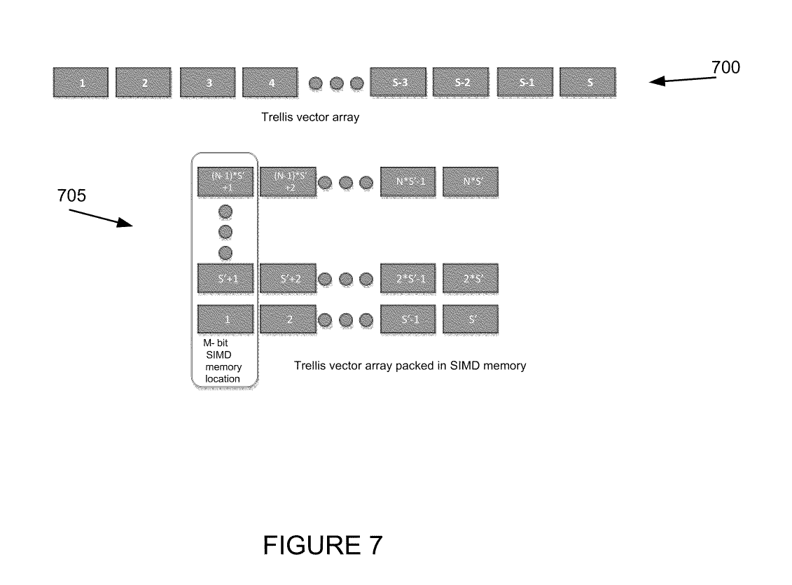

Data arrays to be processed by a SISO decoder may be processed in SIMD lanes within the decoder. FIG. 7 is a diagram of an exemplary trellis-vector array for processing by SIMD lanes. In error correction decoder 140 computations, various data arrays are utilized. The exemplary trellis-vector array maps a data array into a memory for SIMD processing. Let m be the number of SIMD lanes in the programmable processor, and size_lane be the number of bits in each SIMD lane. Then M=m*size_lane may be defined as the size (in bits) of a SIMD operation and a SIMD memory operation. A SIMD data array is defined as a memory array where each array element is a SIMD memory location of size M bits.

Let v be the size of a trellis vector and V=v*size_lane be the number of bits in a trellis vector. A trellis-vector data array may be defined as a software data array, where each element is a vector of size V. In one embodiment, N=M/V, and S is equal to the size of the trellis-vector data array. The trellis-vector array may be segmented into N arrays. The size of each array S′ may be defined as S′=┌N/S┐. The trellis-vector data array may be stored in the memory as a SIMD data array with S′ number of SIMD memory elements. If varray is a trellis-vector data array, and sarray be a SIMD data array, the mapping of elements from varray to sarray can be defined as sarray[i]={varray[i+offset], offset:1˜N}; i:1˜S. In one embodiment, each SIMD data array element stores N trellis-vector data array elements.

Different operations may be used to implement the software modules of an error correction decoder. In one embodiment, SIMD operations may be used to implement an interleaver 220 and deinterleaver 210, for example when using an LTE protocol. When itlv(k) and ditlv(k) are two functions defined for the LTE interleaver 220 and deinterleaver 210, respectively, operations for the LTE interleaver 220 and deinterleaver 210 may be defined as:
Interleaver: out[k]=in[itlv(k)]; k:1˜Sout; and
Deinterleaver: out[k]=in[ditlv(k)]; k:1˜Sout.

The output and input of the interleaver 220 and deinterleaver 210 are represented by the out[k] and in[k] functions. Functions sitlv1(k), sitlv2(k), sditlv1(k), and sditlv2(k) may be defined for SIMD-implementation of the LTE interleaver 220 and deinterleaver 210, m may be the number of SIMD lanes in a programmable processor, and v may be the size of trellis vector. In view of these definitions, n may be defined as n=v/m, and S′out may be defined as S′out=Sout/n. A function f_{mod}(a, b) may be defined for integer input values a and b as fmod(a, b)=a−(a/b)*b. The four functions sitlv1(k), sitlv2(k), sditlv1(k), and sditlv2(k) may be defined such that the following four constraints are met.

f_{mod}(itlv(k), S′ₒᵤₜ)=sitlv1(k); k:1˜S′ₒᵤₜ

itlv(k)=sitlv1(k)+S′ₒᵤₜ*sitlv2(k); k:1˜S′ₒᵤₜ

f_{mod}(ditlv(k),S′ₒᵤₜ)=sditlv1(k); k:1˜S′ₒᵤₜ

ditlv(k)=sditlv1(k)+S′ₒᵤₜ*sditlv2(k); k:1˜S′ₒᵤₜ

Though there may be multiple ways of implementing the functions sitlv1(k), sitlv2(k), sditlv1(k), and sditlv2(k), they should satisfy the above constraints in one exemplary embodiment.

Assuming that the four constraints are satisfied, then Interleaver: out[k]=in[itlv(k)]; k:1˜Sout and Deinterleaver: out[k]=in[ditlv(k)]; k:1˜Sout can be replaced by the following three equations.

f_{shift}(x, offset, x)=x[f_{mod}((k+offset), x)]; k:1˜x

vₒᵤₜ[sitlv1(k)]=f_{shift}(vin[k], sitlv2(k), m); k:1˜S′out

vₒᵤₜ[sditlv1(k)]=f_{shift}(vin[k], sditlv2(k), m); k:1˜S′out

These three equations may be used to implement the SIMD-based interleaver 220 and deinterleaver 210. The output and input are trellis-vector data arrays packed into SIMD data arrays as described above and named vₒᵤₜ and vᵢₙ respectively. This assumes that both the inputs and outputs of the interleaver 220 and deinterleaver 210 are stored in SIMD memory in the pattern as described with respect to FIG. 7. It is noteworthy that in alternate embodiments modules such as the interleaver 220 and deinterleaver 210 need not be SIMD-based.

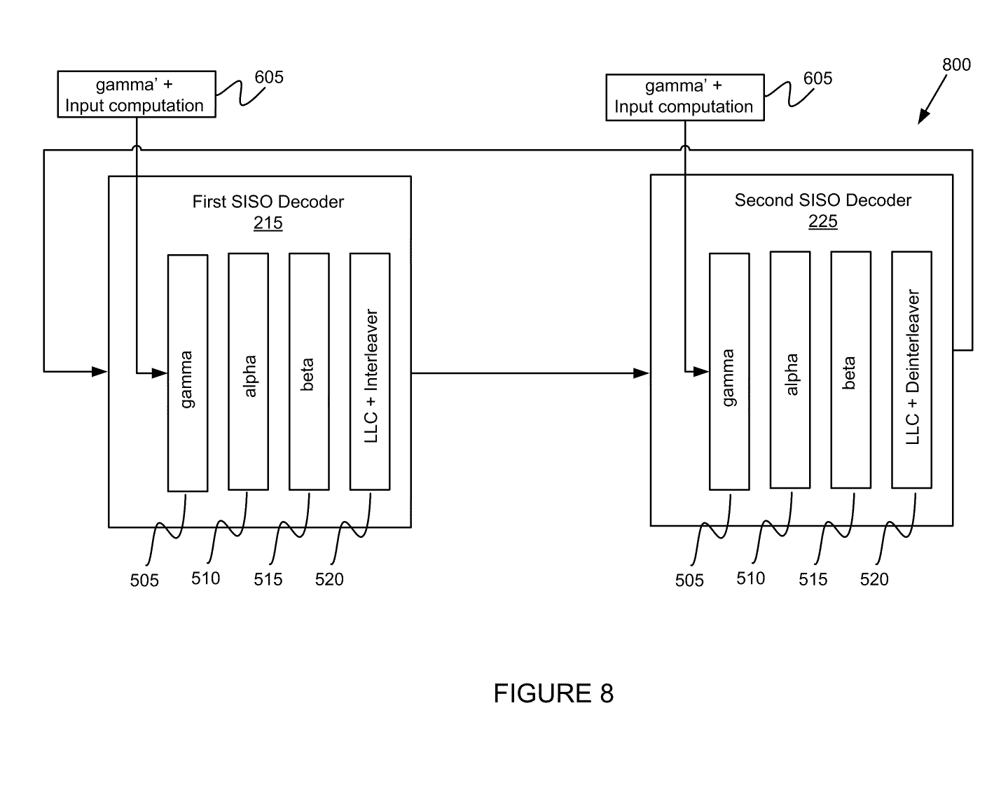

FIG. 8 is a block diagram illustrating an exemplary error correction decoder that combines SISO decoder computations with output operations. In particular, a Max* SISO decoder's SIMD-based LLC computation operations are combined with its output interleaver/deinterleaver operations. An LLC computation may defined as:

LLCₖ=max*ₛ₁(Lₖ)−max*ₛ₀(Lₖ); k:1˜Sₒᵤₜ. eq. 10

A SIMD-based LLC implementation may be defined by the following three equations.

vLLCₖ={LLCₖ₊₁* S′ₒᵤₜ, i:1˜n}

vLₖ={Lₖ₊₁* S′ₒᵤₜ, i:1˜n}

vLLCₖ=max*s1(vLₖ)−max*ₛ₀(vLₖ); k:1˜S′ₒᵤₜ

The first SISO decoder 215 output is communicatively coupled with the interleaver 220, and the output of the second SISO decoder 225 is communicatively coupled with the deinterleaver 210. The SIMD-implementation of the interleaver 220 and deinterleaver 210 are combined with the SIMD-implementation of LLC computation. The output of the SISO decoders may be defined by the following two equations.

vout[sitlv1(k)]=f_{shift}(vLLCₖ[k], sitlv2(k), m); k:1˜S′out

vout[sditlv1(k)]=f_{shift}(vLLCₖ[k], sditlv2(k), m); k:1˜S′out

In one embodiment, for each data point k, vLLCk and interleaver/deinterleaver computations are performed consecutively before the computation for data point k+1 is executed. Thus, reduced error correction decoder computation time is realized.

In some embodiments, the iterative decoding process for performing error correction may be stopped based on one or more states or calculations. In the iterative decoding process of the error correction decoder 140, one iteration of error correction decoding may include completing one call to the sequence of first SISO decoder 215, interleaver 220, second SISO decoder 225, and deinterleaver 210. The number of iterations that may be performed before cessation of error correction decoding may be determined by any of multiple possible methods. In a one embodiment, the number of iterations performed is determined by x=fᵢₜₑᵣ₁[snr]. The function fᵢₜₑᵣ₁[snr] may be any function that returns a value, such as an integer, either greater than zero or a value representing “false,” based on the input of the function. For example, a function may be fᵢₜₑᵣ₁[snr]=C, where C is an integer constant. Signal-to-noise ratio (snr), may be defined as an estimate of the channel condition as given to the error correction decoder 140 as an input. In some embodiments, consecutive calls to fᵢₗₜₑᵣ₁ may not return the same output values. After x iterations of error correction decoding, a cyclic redundancy check CRC check may be applied. If the CRC check returns true, the error correction decoder ends computations. If the CRC check is false, the error correction decoding may perform an additional x=fᵢₗₜₑᵣ₁[snr] number of iterations. Hence, the iterations may continue in this manner until CRC returns true or x is false. In some embodiments, this method for determining the number of iterations to perform may be implemented for an LTE-based error correction decoder 140

Advantageously, the CRC calculation provides for stopping the error correction decoding process after one or more iterations, as soon as the decoding results are determined to be acceptable. Thus, the number of iterations can be reduced as compared to other systems which require a fixed number of iterations

Another method for processing iterations of error correction decoding involves determinations of previous iteration calculations. A number of iterations for a first block may be C₀, where C₀ is an integer constant. Regarding the number of iterations for the ith block, the number of iterations for the ith block may be xᵢ=xᵢ₋₁−C1, where C1 is an integer constant, if the (i−1)th block is decoded correctly. If the (i−1)th block is decoded incorrectly, then the number of iterations for the ith block may be xᵢ=C₂*xᵢ₋₁+C3, where C₂ and C₃ are integer constants.

In another embodiment, a SISO decoder may be implemented in a modified and novel manner. is envisioned. The following Equations 11 through 15 describe one embodiment of max* operations in a SISO decoder.

Lₖ=alphaₖ₋₁(sₖ₋₁)+gammaₖ(sₖ₋₁, sₖ)+betaₖ(sₖ) eq. 11

alphaₖ(sₖ)=max*(alphaₖ₋₁(sₖ₋₁)+gammak(sₖ₋₁, sₖ)) eq. 12

betak(sₖ)=max*(betaₖ₊₁(sₖ₊₁)+gammaₖ₊₁(sₖ, sₖ₊₁)) eq. 13

LLCₖ=max*s1(Lₖ)−max*s0(Lₖ) eq. 14

max*(a, b)=max(a, b)+fₐₚₚᵣₒₓ(|a−b|) eq. 15

In equations 11-15, the BMC, alpha, beta, and LLC calculations may be performed for each data point k in a data array with Sₒᵤₜ elements. It is noted that fₐₚₚᵣₒₓ can be implemented as one or any number of various functions, which are known in the art. For example, fₐₚₚᵣₒₓ may be equal to zero or a constant (computed from environment conditions) in various embodiments. In another embodiment, fₐₚₚᵣₒₓ(x) can be a linear function of x.

In some embodiments of the max* operations, the following equations may be used to calculate alpha, beta, LLC, and max* operations:

alpha′ₖ(sₖ)=fₛₑₗ(alphaₖ, fₐₗₚₕₐ(k, ts(k)), fₐₛₑₗ(k, ts(k))) eq. 16

beta′ₖ(sₖ)=fₛₑₗ(betaₖ, f_{beta}(k, ts(k)), f_{bsel}(k, ts(k))) eq. 17

L′ₖ=fₛₑₗ(Lₖ, f_{L}(k, ts(k)), flsel(k, ts(k))) eq. 18

LLC′ₖ=fₛₑₗ(LLCₖ, f_{LLC}(k, ts(k)), fₗₗₛₑₗ(k, ts(k))) eq. 19

wherein k:1˜Sout; fₛₑₗ(a, b, c)=if (c=true) (a) else (b); fₐₚₚᵣₒₓ₀(k)=0; f_{approxc}(k)=<integer constant>; and max*(a, b)=max(a, b)+fₛₑₗ(fₐₚₚᵣₒₓ₀, f_{approxc}, fₘₛₑₗ(k, ts(k))).

In one embodiment, LLC′ₖ is the output of the Max* computation instead of LLCₖ. The function ts(k) is a function that returns the error correction decoder 140 states (for example, turbo states) at k. The error correction decoder 140 states may be defined as a set of values including all values related to the error correction decoder 140 at point k. This includes, but is not limited to, SNR, the current decoding iteration count, previous iterations' SISO decoder outputs, and previously decoded blocks' output. The functions fₘₛₑₗ, fₐₛₑₗ, f_{bsel}, fₗₛₑₗ, and f_{llcsel} may return either “true” or “false” based on the value of k and ts. The functions fₐₗₚₕₐ, f_{beta}, f_{L} and f_{LLC} may be defined as functions that return a trellis vector of size v, based on inputs k and ts.

In one exemplary embodiment, different max* functions may be used for different channel conditions. If the channel condition is relatively poor, then f_{approxc} (i.e., a function having a constant value) may be used in max*. If the channel condition is relatively good, then fapprox0 (i.e., a function having a value of zero) is used in max*.

In some embodiments, the quality of the channel condition can only be defined with respect to other computations within a transmitter and a receiver. The computations may depend on whether a wireless device is stationary or moving, and how a protocol used for the transmission handles data for a moving device and stationary device. Other calculations that may affect the quality of the channel condition may also include modulation and demodulation schemes.

In some embodiments, iterations may be stopped at some point during an iteration rather than after a whole number of iterations have occurred. For example, at the end of any ½ iteration of an error correction decoder 140 algorithm (yError correction), a sequence of current LLR values have been calculated, r=r₀, r₁, . . . , r_{N-1}. In some embodiments, r may be determined as a probability measure (in LLR form) of the value of the data bits that are being decoded, and the sign indicates the current prediction. A simple early stopping criteria for this error correction decoder 140 algorithm is when CRC (r)=0, in which case the CRC call results in a determination that all the data bits have been decoded correctly.

This technique improves on the mechanism of the early stopping criteria discussed above by examining the pattern of a small number of LLR values that indicate a likelihood of toggling if more yError correction iterations were to be performed. The LLR values may be s₀, s₁, . . . s_{M-1} which are selected from r. The CRC of each 2^{M} combinations of the signs are calculated to determine if any are zero. If any combinations are zero, then it can be assumed that this indicates a correct decoded pattern of the data bits.

For the partial iteration stopping criteria technique, a small number of test candidate LLR values (say between 16 and 24) can be selected during the yError correction process that on average, statistically, yield a correct decode (where the CRC is 0). The speed of calculating the 2^{M} CRC's may be faster than performing another complete ½ iteration of yError correction. The way that this calculation is performed is novel, and leads to a very fast algorithm. In some embodiments, the selection of the test LLR values that yield a correct decode and the speed of the 2^{M} CRCs calculation may be true for use of the partial iteration stopping criteria technique with respect to the yError correction.

This method of performing partial iteration stopping leads higher throughput data rates on average based on improved stopping criteria. An additional result of this approach is that a superior error correction floor can be achieved over what is considered to be attainable with other error correction implementations.

With respect to the partial iteration stopping technique described above, embodiments may involve the following exemplary calculations and operations. Let LLRₖ, 1<k<Sₒᵤₜ be the LLR computation in a SISO decoder, as described in eq. 10. A subset of the LLRₖ values, S′ₒᵤₜ number of LLRₖ values, are selected to be the S′ₒᵤₜ most probable values that are decoded incorrectly. A method of selecting the S′ₒᵤₜ can be, but not limited to, selecting the S′ₒᵤₜ values that are closest to zero.

Let Signₖ, 1<k<Sₒᵤₜ, be the binary values based on the signs of the SISO decoders' LLRₖ values. CRC may be calculated based on Sₖ. Data may be decoded correctly when the CRC returns 0.

Let the indices of the subset of the LLRₖ values, as described above, be defined as Iₖ, 1<k<S′ₒᵤₜ. If CRC calculation does not return 0, the error correction decoder may iterate through all 2^{S′out} combinations of Sₖ binary values at Iₖ indices until a CRC of 0 is returned. The combination of Sₖ binary values that has CRC of 0 is returned as the correctly decoded output.

Let RM be the CRC output of array 1: Sign₁, Sign₂, . . . , Signₖ, . . . Signₛₒᵤₜ₋₁, Signₛₒᵤₜ 1<k<Sₒᵤₜ; let RM′ be the CRC output of array 2: Sign₁, Sign₂, . . . , −1*Signₖ, . . . Signₛₒᵤₜ₋₁, Signₛₒᵤₜ; and let RM″ be the CRC output of array 3: 0₁, 0₂, . . . , −1*Signₖ, . . . 0ₛₒᵤₜ₋₁, 0ₛₒᵤₜ. The calculation of RM′ can be defined by the equality RM′=RM″ xor RM, if array 1 and array 2 only differ by one element at index k.

If RM for Signₖ does not equal to 0, the error correction decoder may use a SIMD to calculate 2^{S′out} combinations of Sₖ binary values until a combination is found to return CRC of 0. Each SIMD lane holds the RM for one of the 2^{S′out} combinations. If the value zero is found in any of the SIMD lanes, then the combination may be the result. Otherwise, the subsequent combination for each of the SIMD lane is calculated following the procedure described in [0082], where array 1 is the original combination, and the array 2 is the subsequent combination.

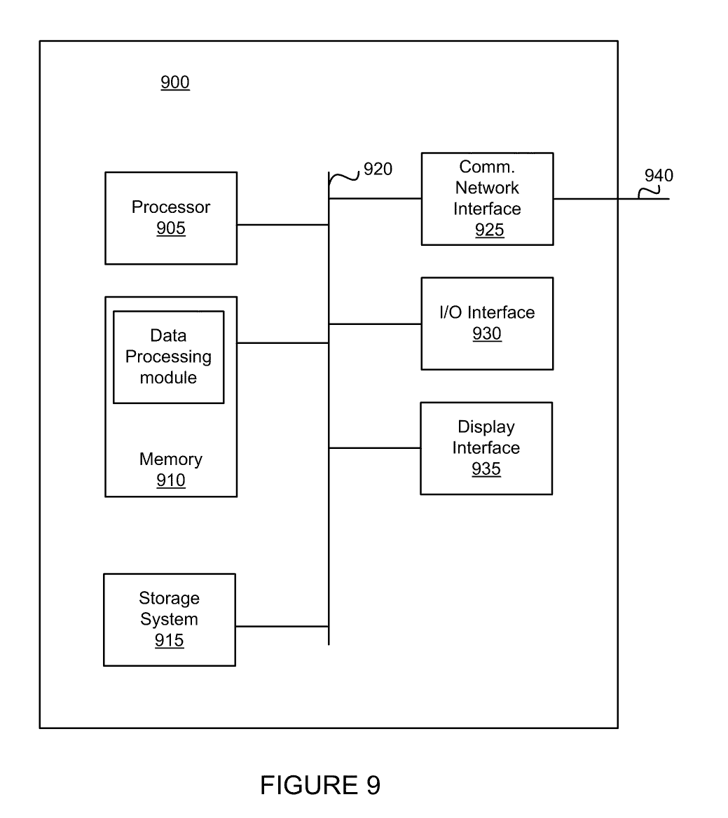

FIG. 9 is a block diagram of exemplary system 900 for running error correction decoder software. System 900 may be used to implement a device suitable for communication and incorporating an error correction decoder implemented via software, such system including for example a wireless device, cellular phone, wireless access point, or other device. In some embodiments, system 900 may implement data transmitter 105 and data receiver 110.

The system 900 of FIG. 9 includes one or more processors 905 and memory 910. Main memory 910 stores, in part, instructions and data for execution by processor 905. Main memory 910 can store the executable code when in operation. The system 900 of FIG. 9 further includes a storage system 915, communication network interface 925, input and output (I/O) devices 930, and a display interface 935.

The components shown in FIG. 9 are depicted as being connected via a single bus 920. The components may be connected through one or more data transport means. Processor 905 and memory 910 may be connected via a local microprocessor bus, and the storage system 915 and display system 770 may be connected via one or more input/output (I/O) buses. The communications network interface 925 may communicate with other digital devices (not shown) via a communications medium.

Storage system 915 may include a mass storage device and portable storage medium drive(s). The mass storage device may be implemented with a magnetic disk drive or an optical disk drive, is a non-volatile storage device for storing data and instructions for use by processor 905. The mass storage device can store the system software for implementing embodiments of the present invention for purposes of loading that software into main memory 910. Some examples of memory system 910 include RAM and ROM.

A portable storage device as part of storage system 915 may operate in conjunction with a portable non-volatile storage medium, such as a floppy disk, compact disk or Digital video disc, to input and output data and code to and from system 900 of FIG. 9. The system software for implementing embodiments of the present invention may be stored on such a portable medium and input to the system 900 via the portable storage device.

The memory and storage system of the system 900 may include a computer-readable storage medium having stored thereon instructions executable by a processor to perform a method for performing error correction on data by a processor. The instructions may include software used to implement modules discussed herein, including a SISO decoder, interleaver, deinterleaver, encoder, computation modules, and other modules.

I/O devices 760 may provide a portion of a user interface, receive audio input (via a microphone), and provide audio output (via a speaker). I/O devices 760 may include an alpha-numeric keypad, such as a keyboard, for inputting alpha-numeric and other information, or a pointing device, such as a mouse, a trackball, stylus, or cursor direction keys.

Display interface 935 may include a liquid crystal display (LCD) or other suitable display device. Display interface 935 receives textual and graphical information, and processes the information for output to the display device.

The foregoing detailed description of the technology herein has been presented for purposes of illustration and description. It is not intended to be exhaustive or to limit the technology to the precise form disclosed. Many modifications and variations are possible in light of the above teaching. For example, software modules discussed herein may be combined, expanded into multiple modules, communicate with all other software modules, and otherwise may be implemented in other configurations. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

What is claimed is:

1. A method for performing error correction on data by a processor, the method comprising:
demultiplexing received data into a first demultiplexer output and a second demultiplexer output;
executing stored instructions by a processor to decode the first demultiplexer output and a deinterleaver output to produce a decoded output;
executing stored instructions by a processor to interleave the decoded output to produce an interleaved output;
executing stored instructions by a processor to decode the interleaved output and the second demultiplexer output to produce decoded data;
executing stored instructions by a processor to deinterleave the decoded data; and
outputting deinterleaved data.

2. The method of claim 1, wherein instructions are executed by a processor to iteratively decode, interleave, and deinterleave data a plurality of times before outputting deinterleaved data.

3. The method of claim 1, the processor configured to perform operations on a plurality of SIMD lanes,
wherein instructions are executed by the processor to implement a soft-in soft-out (SISO) decoder,
the implemented SISO decoder configured to determine a probability for a current state value based on past values, a probability for a current state value transition, a probability for a current state based on future values, and a log likelihood calculation (LLC),
the values for the current state probabilities and LLC determined in parallel over the plurality of SIMD lanes.

4. The method of claim 3, wherein the probability for a current state value based on past values, the probability for a current state value transition, the probability for a current state based on future values, and the LLC are performed in parallel on SIMD lanes of the processor.

5. The method of claim 3, wherein the calculations performed for a current state value transition computation are reduced by pre-computing before multiple iterations of error correction decoding are performed.

6. The method of claim 5, wherein values in BMs and BMp are stored as SIMD data arrays before a error correction decoder computation is performed.

7. The method of claim 1, further comprising combining at least a part of SIMD-based probability for a current state value transition computation operations with input operations.

8. The method of claim 1, wherein the processor is a programmable processor with a trellis vector data array layout in a memory of the processor, the trellis vector data array layout configured for SIMD operations used in the error correction decoder.

9. The method of claim 1, further comprising using SIMD operations to implement the interleaver and the deinterleaver for a Long Term Evolution (LTE) protocol.

10. The method of claim 1, further comprising combining Max* SISO decoder SIMD-based LLC computation operations with operations of an interleaver.

11. The method of claim 1, further comprising combining Max* SISO decoder SIMD-based LLC computation operations with operations of a deinterleaver.

12. The method of claim 1, further comprising performing a cyclic redundancy check (CRC) after x=fᵢₜₑᵣ₁(snr) iterations of error correction decoding.

13. The method of claim 1, further comprising iteratively processing multiple blocks through the error correction decoder, the iterative processing including determining whether to continue the processing after a set number of iterations.

14. The method of claim 1, wherein ts(k) is a function that returns error correction decoder states at k, and the error correction decoder states are defined as a set of values including all values related to the error correction decoder at point k, wherein these values include SNR, a current decoding iteration count, SISO decoder outputs of previous iterations, and previously decoded blocks' output.

15. The method of claim 1, wherein at the end of a ½ iteration of a error correction decoder 140 algorithm a sequence of current LLR values have been calculated, denoted r=r₀, r₁, . . . , r_{N-1}, wherein r is a probability measure in LLR form of a value of data bits that are being decoded, and a sign indicates the current prediction.

16. The method of claim 15, wherein an early stopping criteria for the error correction decoder algorithm is when a cyclic redundancy check of r is equal to zero.

17. The method of claim 1, wherein the decoding is performed by a SISO decoder that calculates an alpha value, beta value, and LLC value based in part on a plurality of binary functions.

18. The method of claim 1, further comprising computing a cyclic redundancy check (CRC) of a sequence of decoded binary elements based on the CRC of another sequence of decoded binary elements.

19. The method of claim 18, the CRC computation includes correcting erroneously decoded bits.

20. The method of claim 19, wherein the CRC computation is performed using SIMD.

21. A system for performing error correction, the system comprising:
a processor;
a demultiplexing module stored in memory and executed by a processor to demultiplex an input into a first demultiplexer output and a second demultiplexer output;
a first decoder module stored in memory and executed by a processor to decode the first demultiplexer output and a deinterleaver output to produce a decoded output;
an interleaver module stored in memory and executed by a processor to deinterleave the decoded output to produce an interleaved output;
a second decoder module stored in memory and executed by a processor to decode the interleaved output and the second demultiplexer output to produce decoded data; and
a deinterleaver module stored in memory and executed by a processor to deinterleave the decoded data and provide deinterleaved data.

22. The system of claim 21, the system configured to perform operations on a plurality of SIMD lanes,
wherein a decoder module is a SISO decoder module configured to determine a probability for a current state value based on past values, a probability for a current state value transition, a probability for a current state based on future values, and a log likelihood calculation (LLC),
the values for the current state probabilities and LLC determined in parallel over the plurality of SIMD lanes.

23. The system of claim 22, wherein the probability for a current state value based on past values, the probability for a current state value transition, the probability for a current state based on future values, and the LLC are performed in parallel on SIMD lanes of the processor.

24. The system of claim 23, wherein the probability for a current state value transition computation is reduced by pre-computing, before multiple iterations of error correction decoding are performed, both a data array of branch metric values based on systemic bits (BMs), and a data array of branch metric values based on parity bits (BMp).

25. A computer-readable storage medium having stored thereon instructions executable by a processor to perform a method for performing error correction on data by a processor, the method comprising:
demultiplexing received data into a first demultiplexer output and a second demultiplexer output;
executing stored instructions by a processor to decode the first demultiplexer output and a deinterleaver output to produce a decoded output;
executing stored instructions by a processor to interleave the decoded output to produce an interleaved output;
executing stored instructions by a processor to decode the interleaved output and the second demultiplexer output to produce decoded data;
executing stored instructions by a processor to deinterleave the decoded data; and
outputting deinterleaved data.
